(19) United States
(12) Patent Application Publication
(10) Pub. No.: US 2020/0075446 A1
(43) Pub. Date: Mar. 5, 2020

(54) ELECTRONIC DEVICE PACKAGE

(71) Applicant: Intel Corporation, Santa Clara, CA (US)

(72) Inventors: Juan E. Dominguez, Chandler, AZ (US); Hyoung Il Kim, Folsom, CA (US)

(73) Assignee: Intel Corporation, Santa Clara, CA (US)

(21) Appl. No.: 16/467,976

(22) PCT Filed: Dec. 31, 2016
(86) PCT No.: PCT/US2016/069645

§ 371 Date: Jun. 9, 2019

(51) Int. Cl. H01L 23/31; H01L 23/367; H01L 23/538; H01L 25/065

(52) U.S. Cl. CPC H01L 23/3121; H01L 23/3677; H01L 2224/04105; H01L 25/0657; H01L 2225/06589; H01L 23/5383

(57) ABSTRACT

Electronic device package technology is disclosed. An electronic device package can comprise a substrate. The electronic device package can also comprise a thermally conductive post extending from the substrate. In addition, the electronic device package can comprise an electronic component supported by the thermally conductive post. The thermally conductive post can facilitate heat transfer between the electronic component and the substrate. Associated systems and methods are also disclosed.

### TECHNICAL FIELD

Embodiments described herein relate generally to electronic device packages, and more particularly to thermal management in electronic device packages.

### BACKGROUND

Due to the growing popularity of mobile phones, tablets, wearable devices, digital cameras, and other small form factor applications, integrated systems in such devices have high component densities. Some package configurations stack multiple dies to save space. For example, a mixed logic-memory stack includes a memory component (e.g., DRAM, SRAM, FLASH, etc.) stacked on a logic or processor component. A logic or processor component can include an application specific integrated circuit (ASIC), such as a processor and/or a system on a chip (SOC), which may integrate a CPU, a GPU, a memory controller, a video decoder, an audio decoder, a video encoder, a camera processor, system memory, and/or a modem onto a single chip. Thermal management in highly integrated systems is becoming more important with dies and active components placed ever closer together.

### BRIEF DESCRIPTION OF THE DRAWINGS

Invention features and advantages will be apparent from the detailed description which follows, taken in conjunction with the accompanying drawings, which together illustrate, by way of example, various invention embodiments; and, wherein:

FIG. 1 illustrates a schematic cross-section of an electronic device package in accordance with an example embodiment;

FIG. 2 illustrates a schematic cross-section of an electronic device package in accordance with an example embodiment;

FIG. 3 illustrates a schematic cross-section of an electronic device package in accordance with an example embodiment;

FIG. 4 illustrates a schematic cross-section of an electronic device package in accordance with an example embodiment;

FIGS. 5A-5E illustrates aspects of a method for making an electronic device package in accordance with an example embodiment; and

FIG. 6 is a schematic illustration of an exemplary computing system.

Reference will now be made to the exemplary embodiments illustrated, and specific language will be used herein to describe the same. It will nevertheless be understood that no limitation of the scope or to specific invention embodiments is thereby intended.

### DESCRIPTION OF EMBODIMENTS

Before invention embodiments are disclosed and described, it is to be understood that no limitation to the particular structures, process steps, or materials disclosed herein is intended, but also includes equivalents thereof as would be recognized by those ordinarily skilled in the relevant arts. It should also be understood that terminology employed herein is used to describe particular examples only and is not intended to be limiting. The same reference numerals in different drawings represent the same element. Numbers provided in flow charts and processes are provided for clarity in illustrating steps and operations and do not necessarily indicate a particular order or sequence. Unless defined otherwise, all technical and scientific terms used herein have the same meaning as commonly understood by one of ordinary skill in the art to which this disclosure belongs.

As used in this written description, the singular forms “a,” “an” and “the” provide express support for plural referents unless the context clearly dictates otherwise. Thus, for example, reference to “a layer” includes a plurality of such layers.

In this application, “comprises,” “comprising,” “containing” and “having” and the like can have the meaning ascribed to them in U.S. Patent law and can mean “includes,” “including,” and the like, and are generally interpreted to be open ended terms. The terms “consisting of” or “consists of” are closed terms, and include only the components, structures, steps, or the like specifically listed in conjunction with such terms, as well as that which is in accordance with U.S. Patent law. “Consisting essentially of” or “consists essentially of” have the meaning generally ascribed to them by U.S. Patent law. In particular, such terms are generally closed terms, with the exception of allowing inclusion of additional items, materials, components, steps, or elements, that do not materially affect the basic and novel characteristics or function of the item(s) used in connection therewith. For example, trace elements present in a composition, but not affecting the composition's nature or characteristics would be permissible if present under the “consisting essentially of” language, even though not expressly recited in a list of items following such terminology. When using an open ended term in the written description like “comprising” or “including,” it is understood that direct support should be afforded also to “consisting essentially of” language as well as “consisting of” language as if stated explicitly and vice versa.

The terms “first,” “second,” “third,” “fourth,” and the like in the description and in the claims, if any, are used for distinguishing between similar elements and not necessarily for describing a particular sequential or chronological order. It is to be understood that the terms so used are interchangeable under appropriate circumstances such that the embodiments described herein are, for example, capable of operation in sequences other than those illustrated or otherwise described herein. Similarly, if a method is described herein as comprising a series of steps, the order of such steps as presented herein is not necessarily the only order in which such steps may be performed, and certain of the stated steps may possibly be omitted and/or certain other steps not described herein may possibly be added to the method.

The terms “left,” “right,” “front,” “back,” “top,” “bottom,” “over,” “under,” and the like in the description and in the claims, if any, are used for descriptive purposes and not necessarily for describing permanent relative positions. It is to be understood that the terms so used are interchangeable under appropriate circumstances such that the embodiments described herein are, for example, capable of operation in other orientations than those illustrated or otherwise described herein.

The term “coupled,” as used herein, is defined as directly or indirectly connected in an electrical or nonelectrical manner. “Directly coupled” objects or items are in physical contact with and attached to one another. Objects described herein as being “adjacent to” each other may be in physical contact with each other, in close proximity to each other, or in the same general region or area as each other, as appropriate for the context in which the phrase is used.

Occurrences of the phrase “in one embodiment,” or “in one aspect,” herein do not necessarily all refer to the same embodiment or aspect.

As used herein, the term “substantially” refers to the complete or nearly complete extent or degree of an action, characteristic, property, state, structure, item, or result. For example, an object that is “substantially” enclosed would mean that the object is either completely enclosed or nearly completely enclosed. The exact allowable degree of deviation from absolute completeness may in some cases depend on the specific context. However, generally speaking the nearness of completion will be so as to have the same overall result as if absolute and total completion were obtained. The use of “substantially” is equally applicable when used in a negative connotation to refer to the complete or near complete lack of an action, characteristic, property, state, structure, item, or result. For example, a composition that is “substantially free of” particles would either completely lack particles, or so nearly completely lack particles that the effect would be the same as if it completely lacked particles. In other words, a composition that is “substantially free of” an ingredient or element may still actually contain such item as long as there is no measurable effect thereof.

As used herein, the term “about” is used to provide flexibility to a numerical range endpoint by providing that a given value may be “a little above” or “a little below” the endpoint.

As used herein, a plurality of items, structural elements, compositional elements, and/or materials may be presented in a common list for convenience. However, these lists should be construed as though each member of the list is individually identified as a separate and unique member. Thus, no individual member of such list should be construed as a de facto equivalent of any other member of the same list solely based on their presentation in a common group without indications to the contrary.

Concentrations, amounts, sizes, and other numerical data may be expressed or presented herein in a range format. It is to be understood that such a range format is used merely for convenience and brevity and thus should be interpreted flexibly to include not only the numerical values explicitly recited as the limits of the range, but also to include all the individual numerical values or sub-ranges encompassed within that range as if each numerical value and sub-range is explicitly recited. As an illustration, a numerical range of “about 1 to about 5” should be interpreted to include not only the explicitly recited values of about 1 to about 5, but also include individual values and sub-ranges within the indicated range. Thus, included in this numerical range are individual values such as 2, 3, and 4 and sub-ranges such as from 1-3, from 2-4, and from 3-5, etc., as well as 1, 2, 3, 4, and 5, individually.

This same principle applies to ranges reciting only one numerical value as a minimum or a maximum. Furthermore, such an interpretation should apply regardless of the breadth of the range or the characteristics being described.

Reference throughout this specification to “an example” means that a particular feature, structure, or characteristic described in connection with the example is included in at least one embodiment. Thus, appearances of the phrases “in an example” in various places throughout this specification are not necessarily all referring to the same embodiment.

Furthermore, the described features, structures, or characteristics may be combined in any suitable manner in one or more embodiments. In this description, numerous specific details are provided, such as examples of layouts, distances, network examples, etc. One skilled in the relevant art will recognize, however, that many variations are possible without one or more of the specific details, or with other methods, components, layouts, measurements, etc. In other instances, well-known structures, materials, or operations are not shown or described in detail but are considered well within the scope of the disclosure.

### Example Embodiments

An initial overview of technology embodiments is provided below and specific technology embodiments are then described in further detail. This initial summary is intended to aid readers in understanding the technology more quickly but is not intended to identify key or essential features of the technology nor is it intended to limit the scope of the claimed subject matter.

Typically, thermal management solutions for integrated systems present options that occupy area on package substrates and increase cost. In addition, the stacking of dies with different sizes requires adding spacers and therefore can add process steps and costs. Accordingly, in one embodiment, an electronic device package is disclosed that provides a thermal dissipation solution that does not consume additional area on package substrates or increase costs. In one aspect, the thermal dissipation solution can also provide support for electronic components (e.g., stacked dies), such as by serving as a spacer, which can also eliminate process steps and costs in conventional packaging. In another aspect, the thermal dissipation solution can also provide electrical circuitry, such as simple signal or power routing. In one example, an electronic device package in accordance with the present disclosure can comprise a substrate. The electronic device package can also comprise a thermally conductive post extending from the substrate. In addition, the electronic device package can comprise an electronic component supported by the thermally conductive post. The thermally conductive post can facilitate or accelerate heat transfer between the electronic component and the substrate. Associated systems and methods are also disclosed.

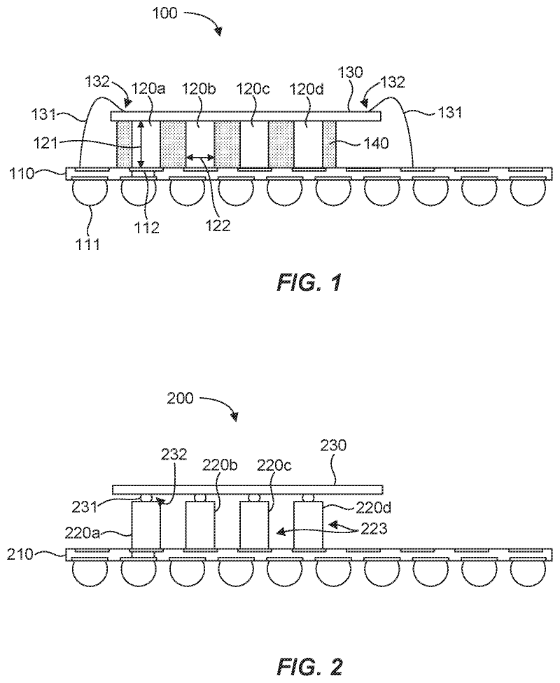

Referring to FIG. 1, an exemplary electronic device package 100 is schematically illustrated in cross-section. The electronic device package 100 can include a substrate 110. The substrate 110 may include typical substrate materials. For example, the substrate may comprise an epoxy-based laminate substrate having a core and/or build-up layers. The substrate 110 may include other suitable types of substrates in other embodiments. For example, the substrate can be formed primarily of any suitable semiconductor material (e.g., a silicon, gallium, indium, germanium, or variations or combinations thereof, among other substrates). Additionally, the substrate can have one or more insulating layers, such as a glass-reinforced epoxy, FR-4, polytetrafluoroethylene (Teflon), cotton-paper reinforced epoxy (CEM-3), phenolic-glass (G3), paper-phenolic (FR-1 or FR-2), polyester-glass (CEM-5), ABF (Ajinomoto Build-up Film), or any other dielectric material, for example glass, or any combination thereof that can be used in printed circuit boards (PCBs).

In one aspect, the substrate 110 can be configured to facilitate electrically coupling the electronic device package 100 with an external electronic component, such as another substrate (e.g., a circuit board such as a motherboard) to further route electrical signals and/or to provide power. The electronic device package 100 can include interconnects, such as solder balls 111, coupled to the substrate 110 for electrically coupling the electronic device package 100 with an external electronic component.

The electronic device package 100 can also include one or more thermally conductive posts 120a-d extending from the substrate 110. The thermally conductive posts 120a-d can be made of any suitable thermally conductive material, such as a metal material (e.g., aluminum, copper, silver, various metallic alloys, etc.). The thermally conductive posts 120a-d can have any suitable height 121, which may be the same as another thermally conductive post or different from another thermally conductive post. In one aspect, the thermally conductive posts 120a-d can have a height 121 of from about 50 μm to about 150 μm (e.g., about 120 μm in some embodiments). The thermally conductive posts 120a-d can have any suitable thickness or diameter 122, which may be the same as another thermally conductive post or different from another thermally conductive post. In one aspect, the thermally conductive posts 120a-d can have a thickness or diameter 122 of from about 50 μm to about 150 μm (e.g., about 100 μm in some embodiments). The thermally conductive posts 120a-d can have a constant or varying thickness or diameter 122 along the height 121.

The electronic device package 100 can also include an electronic component 130 supported at least partially by the thermally conductive posts 120a-d. The thermally conductive posts 120a-d can facilitate or accelerate heat transfer between the electronic component 130 and the substrate 110. An electronic component can be any electronic device or component that may be included in an electronic device package, such as a semiconductor device (e.g., a die, a chip, a processor, computer memory, etc.). In one embodiment, the electronic component 130 may represent a discrete chip, which may include an integrated circuit. The electronic component 130 may be, include, or be a part of a processor, memory (e.g., ROM, RAM, EEPROM, flash memory, etc.), or an application specific integrated circuit (ASIC). In some embodiments, the electronic component 130 can be a system-on-chip (SOC) or a package-on-package (POP). In some embodiments, the electronic device package 100 can be a system-in-a-package (SIP).

The electronic component 130 can be electrically coupled to the substrate 110 using interconnect structures 131 (e.g., the illustrated wirebonds and/or solder balls) configured to route electrical signals between the electronic component 130 and the substrate 110. In some embodiments, the interconnect structures 131 may be configured to route electrical signals such as, for example, I/O signals and/or power or ground signals associated with the operation of the electronic component 130. The electronic component 130 can have electrical interconnect interfaces 132 (e.g., pads) to interface and form electrical connections with the interconnect structures 131. Thus, for example, the electronic component 130 of FIG. 1 is electrically coupled to the substrate 110 via wirebond interconnect structures 131 extending between the electrical interconnect interface 132 and the substrate 110. For such connections, the electrical interconnect interfaces 132 are typically oriented away from the substrate 110.

The substrate 110 may include electrical routing features 112 configured to route electrical signals to or from the electronic component 130. The electrical routing features may be internal and/or external to the substrate 110. For example, in some embodiments, the substrate 110 may include electrical routing features such as pads, vias, and/or traces as commonly known in the art configured to receive the interconnect structures 131 (e.g., wire bonds in FIG. 1) and route electrical signals to or from the electronic component 130. The pads, vias, and traces of the substrate 110 can be constructed of the same or similar electrically conductive materials, or of different electrically conductive materials. In one aspect, the substrate 110 can be configured as a redistribution layer.

The thermally conductive posts 120a-d can transfer heat from the electronic component 130 to the substrate 110. Generally, therefore, the thermally conductive posts 120a-d will be in direct contact with the electronic component 130 and the substrate 110 for efficient heat transfer therebetween. The substrate 110 can transfer heat into the solder balls 111 and from the solder balls 111 to an external device, which may include or be thermally coupled to a cooling system (e.g., a heat sink, a heat spreader, etc.). In one aspect, the thermally conductive posts 120a-d can be coupled to or in contact with a thermally conductive portion of the substrate 110, such as to the electrical routing features 112, which may be coupled to the solder balls 111. Thus, the thermally conductive posts 120a-d can provide a heat transfer path from the electronic component 130 to the substrate 110 to remove heat from the electronic component 130, which may provide a more efficient and desirable heat transfer path than heat dissipation from an opposite or top side of the electronic component 130. The arrangement of the thermally conductive posts 120a-d with the electronic component 130 and the substrate 110 can therefore act as a thermal dissipation solution for the electronic component 130. Any suitable number of thermally conductive posts 120a-d in any suitable arrangement or configuration can be utilized to achieve a desired thermal effect (e.g., to distribute heat). Because the thermally conductive posts 120a-d are disposed between the electronic component 130 and the substrate 110, the thermally conductive posts 120a-d can provide a thermal management solution that does not occupy any additional “real estate” or area on the substrate 110.

In one aspect, a mold compound material 140 (e.g., an epoxy) can at least partially encapsulate or overmold one or more of the thermally conductive posts 120a-d. For example, FIG. 1 shows the mold compound 140 encapsulating all of the thermally conductive posts 120a-d. As mentioned above, it is desirable to maintain the top or contact portions of the thermally conductive posts 120a-d free of mold compound material so that there may be direct contact between the thermally conductive posts 120a-d and the electronic component 130 for more efficient heat transfer. The top or contact portions of the thermally conductive posts 120a-d and a top portion of the mold compound 140 can form a planar or flat surface to interface with the electronic component 130, which can be disposed on at least a portion of the planar surface.

The height 121 of the thermally conductive posts 120a-d can be configured to support the electronic component 130 at a desired position or height above the substrate 110. Thus, in one aspect, the thermally conductive posts 120a-d (and mold compound 140 in some embodiments) can serve as a spacer for the electronic component 130 from the substrate 110. The thermally conductive posts 120a-d and mold compound 140 can therefore be configured (e.g., in number, shape, size, etc. as applicable) to serve as a thermal dissipation solution and optionally as a spacer for the electronic component 130.

FIG. 2 schematically illustrates a cross-section of an electronic device package 200 in accordance with another example embodiment. The electronic device package 200 is similar to the electronic device package 100 of FIG. 1 in many respects. For example, the electronic device package 200 includes a substrate 210, thermally conductive posts 220a-d extending from the substrate 210, and an electronic component 230 supported by the thermally conductive posts 220a-d.

In this case, the electronic component 230 is coupled to the thermally conductive posts 220a-d via solder balls 231, which may provide an effective thermal coupling. In one aspect, the thermally conductive posts 220a-d may be electrically conductive and configured to route electrical signals such as, for example, I/O signals and/or power or ground signals associated with the operation of the electronic component 230. Thus, the thermally conductive posts 220a-d can be electrically coupled to the substrate 210 and the electronic component 230 (e.g., via the solder balls 231). An electrical interconnect interface 232 of the electronic component 230 can therefore be oriented toward the substrate 210 (e.g., a flip chip configuration) to facilitate such an electrical coupling between the electronic component 230 and the thermally conductive posts 220a-d. A thermally conductive post can be made of any suitable conductive material, (e.g., a metal material such as aluminum, copper, silver, metal alloys, etc.). In some embodiments, a thermally conductive post can have an electrical resistance less than about 0.02-0.05 ohms, which may depend on thickness and material selection.

In addition, the electronic device package 200 does not include mold compound encapsulating the thermally conductive posts 220a-d. In this embodiment, the thermally conductive posts 220a-d have their side portions 223 are exposed to an open space and may release heat at a different rate than when surrounded by mold compound (e.g. a higher dissipation rate).

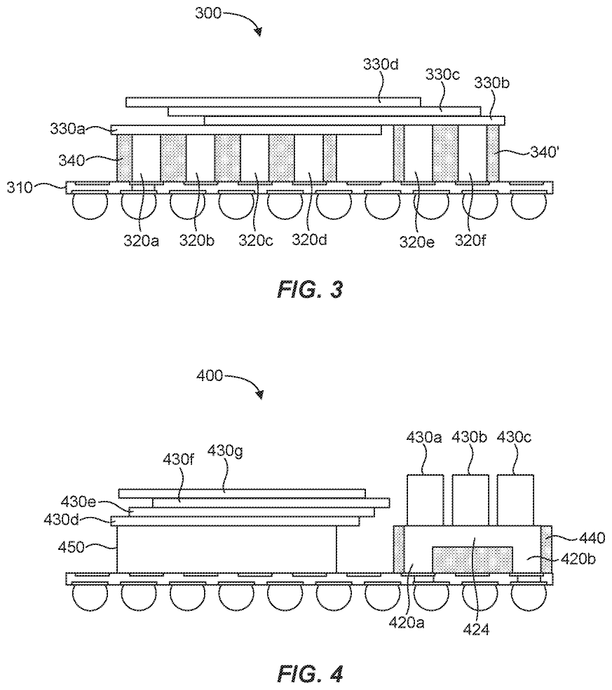

FIG. 3 schematically illustrates a cross-section of an electronic device package 300 in accordance with another example of the present disclosure. In this case, the electronic device package 300 includes multiple electronic components 330a-d in a stacked relationship or arrangement, for example, to save space and provide smaller form factors. Although four electronic components 330a-d are depicted in FIG. 3, any suitable number of electronic components can be included in a stack. The electronic components in a stack can be of the same or different sizes and can be laterally offset or off-center as shown in FIG. 3. Die attach film (not shown) can be disposed between adjacent electronic components, which can provide benefits during assembly of the electronic device package 300. The electronic device package 300 also includes thermally conductive posts 320a-f extending from a substrate 310 to transfer heat from the electronic components 330a-d to the substrate 310. Due to the laterally offset nature of the stack, the thermally conductive posts 320a-d can be in direct contact with the electronic component 330a, and the thermally conductive posts 320e-f can be in direct contact with the electronic component 330b. The thermally conductive posts 320a-f can transfer heat from the stack of electronic components 330a-d, which is distributed among the thermally conductive posts 320a-f. In addition, the thermally conductive posts 320a-d can be at least partially encapsulated by a mold compound 340, and the thermally conductive posts 320e-f can be at least partially encapsulated by a mold compound 340′.

Additionally, the thermally conductive posts 320a-d and mold compound 340 support all of the electronic components 330a-d, and the thermally conductive posts 320e-f and mold compound 340′ support fewer than all of the electronic components 330a-d. Specifically, the thermally conductive posts 320e-f and mold compound 340′ support the electronic components 330b-d, which are laterally offset from the electronic component 330a. The thermally conductive posts 320e-f and mold compound 340′ can therefore serve as a spacer to support the laterally offset electronic components 330b-d.

FIG. 4 schematically illustrates a cross-section of an electronic device package 400 in accordance with another example of the present disclosure. In this case, the electronic device package 400 includes thermally conductive posts 420a-b coupled to a substrate 410, and a laterally oriented bridge 424 extending between the thermally conductive posts 420a-b. A mold compound 440 can at least partially encapsulate the thermally conductive posts 420a-b and the bridge 424. Electronic components 430a-c can be in communication (e.g., in direct contact) with the bridge 424 to facilitate heat transfer from the electronic components 430a-c to the bridge 424, which can transfer heat to the thermally conductive posts 420a-b. In addition to the thermal benefits provided by the thermally conductive posts 420a-b as described herein, the thermally conductive posts 420a-b and the bridge 424 can be electrically conductive and electrically coupled to the electronic components 430a-c and the substrate 410. Thus, the thermally conductive posts 420a-b and the bridge 424 can provide electrical routing (e.g., power and/or signals) for the electronic components 430a-c. In some embodiments, the thermally conductive posts 420a-b and the bridge 424 can be used for simple routing (e.g., common signal components). This can reduce complexity of the substrate 410 by minimizing routing in the substrate 410 and reduce the maximum current in the substrate 410.

In addition, the electronic device package 400 can include a spacer 450 disposed on the substrate 410 and one or more electronic components 430d-g supported by the spacer 450, which may be in a stacked arrangement (as illustrated in FIG. 4). The spacer 450 can be a conventional spacer or may include one or more conductive posts (not shown) as described herein to facilitate heat transfer and, optionally, electrical routing for the electronic components 430d-g.

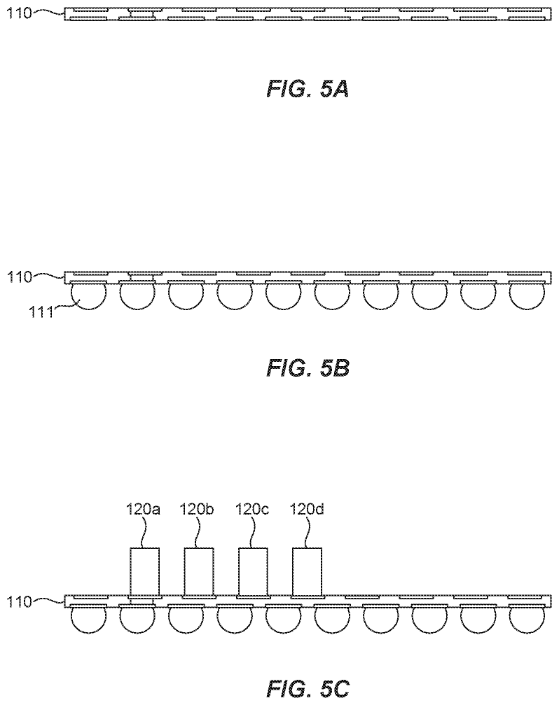

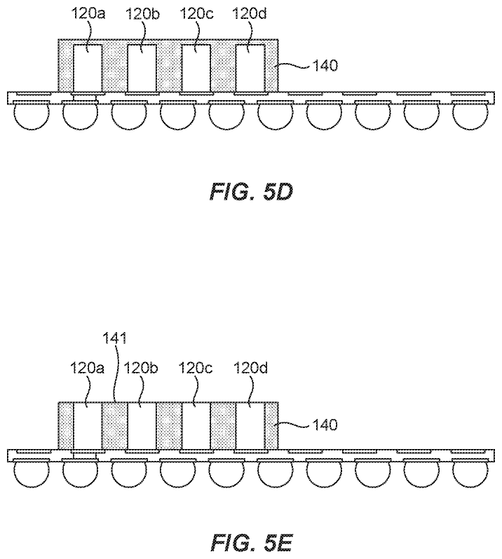

FIGS. 5A-5E illustrate aspects of a method for making an electronic device package in accordance with one example embodiment, such as the electronic device package 100. FIG. 5A schematically illustrates a side cross-sectional view of the substrate 110 of an electronic component. In some embodiments, the substrate 110 can be or include a redistribution layer. Solder balls (e.g., the solder balls 111) can be added to the substrate 110, as shown in FIG. 5B. As shown in FIG. 5C, thermally conductive posts 120a-d can be disposed on the substrate 110, such as on interconnects pads. The thermally conductive posts 120a-d can be disposed on the substrate 110 utilizing any suitable technique or process. For example, the thermally conductive posts 120a-d can be “grown” on the substrate 110 utilizing a deposition process (e.g., plating, printing, sputtering, etc.). Lengths or heights of the thermally conductive posts 120a-d extending from the substrate 110 can be the same or different. For example, the thermally conductive posts 120a-d can each have any suitable length. Length variation of the thermally conductive posts 120a-d can be accomplished by changing the current density on a particular substrate area and/or by a material removal process (e.g., polishing). The thermally conductive posts 120a-d can be polished to obtain uniform heights if desired. In one aspect, the thermally conductive posts 120a-d can be disposed on the substrate 110 as part of the substrate fabrication process. The configuration illustrated in FIG. 5C represents one embodiment of an electronic device package precursor, where side portions of the thermally conductive posts 120a-d are exposed to atmosphere. An electronic device package precursor can be subjected to further processing as disclosed herein to create an electronic device package in accordance with the present disclosure. For example, an electronic component can be disposed on the thermally conductive posts and coupled with solder balls to arrive at the embodiment shown in FIG. 2.

As shown in FIG. 5D, the thermally conductive posts 120a-d can be at least partially encapsulated or over-molded in mold compound 140 (e.g., epoxy). Top portions of the thermally conductive posts 120a-d may be covered by the mold compound. The configuration illustrated in FIG. 5D represents another embodiment of an electronic device package precursor. The electronic device package precursor can be subjected to further processing as disclosed herein to create an electronic device package in accordance with the present disclosure. For example, mold compound covering the top portion of the thermally conductive posts 120a-d can be removed to expose the thermally conductive posts 120a-d, as shown in FIG. 5E. Mold compound can be removed by any suitable process or technique, such as polishing, which can form the top portion of the thermally conductive posts 120a-d and the mold compound 140 into a planar or flat surface 141 (e.g., with uniform height thermally conductive posts 120a-d) to interface with an electronic component. The configuration illustrated in FIG. 5E represents yet another embodiment of an electronic device package precursor. The electronic device package precursor can be subjected to further processing as disclosed herein to create an electronic device package in accordance with the present disclosure. For example, an electronic component can be disposed on the thermally conductive posts 120a-d and mold compound 140, and the electronic component can be electrically coupled to the substrate 110 (e.g., via wirebonds) to arrive at the embodiment shown in FIG. 1.

It should be recognized that the configuration of thermally conductive posts, mold compound, and electronic components can be varied to arrive at the electronic device package embodiments shown in FIGS. 3 and 4 or other embodiments. The thermally conductive posts and other features disclosed herein can provide a thermal management solution that does not occupy area or real estate on the substrate or require additional steps in the assembly process and therefore does not increase cost. The thermally conductive posts can also serve as spacers for stacked dies of different sizes, thus avoiding process steps and costs associated with typical spacers for the dies.

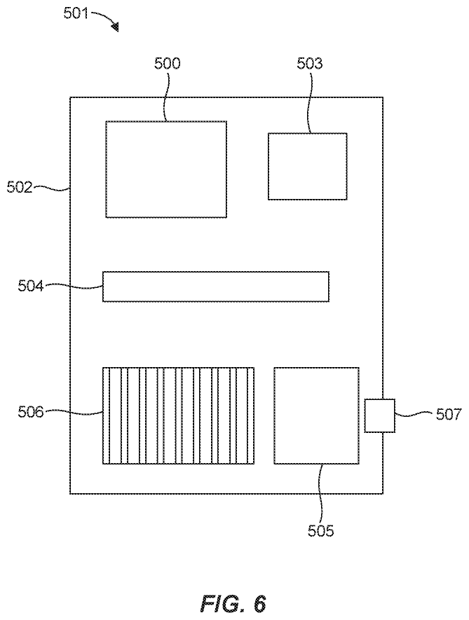

FIG. 6 schematically illustrates an example computing system 501. The computing system 501 can include an electronic device package 500 as disclosed herein, coupled to a motherboard 502. In one aspect, the computing system 501 can also include a processor 503, a memory device 504, a radio 505, a cooling system (e.g., a heat sink and/or a heat spreader) 506, a port 507, a slot, or any other suitable device or component, which can be operably coupled to the motherboard 502. The computing system 501 can comprise any type of computing system, such as a desktop computer, a laptop computer, a tablet computer, a smartphone, a server, a wearable electronic device, etc. Other embodiments need not include all of the features specified in FIG. 6, and may include alternative features not specified in FIG. 6.

### EXAMPLES

The following examples pertain to further embodiments.

In one example there is provided, an electronic device package comprising a substrate, a thermally conductive post extending from the substrate, and an electronic component supported by the thermally conductive post, wherein the thermally conductive post facilitates heat transfer between the electronic component and the substrate.

In one example of an electronic device package, an electrical interconnect interface of the electronic component is oriented away from the substrate.

In one example of an electronic device package, the electronic component is electrically coupled to the substrate via a wirebond extending between the electrical interconnect interface and the substrate.

In one example, an electronic device package precursor comprises a mold compound at least partially encapsulating the thermally conductive post.

In one example of an electronic device package, a top portion of the mold compound and a top portion of the thermally conductive post form a planar surface, and the electronic component is disposed on at least a portion of the planar surface.

In one example of an electronic device package, the mold compound comprises an epoxy.

In one example of an electronic device package, a side portion of the thermally conductive post is exposed to atmosphere.

In one example of an electronic device package, the electronic component comprises a plurality of electronic components in a stacked arrangement.

In one example, an electronic device package precursor comprises a second thermally conductive post extending from the substrate, wherein the first thermally conductive post supports all of the plurality of electronic components and the second thermally conductive posts supports fewer than all of the plurality of electronic components.

In one example of an electronic device package, the first thermally conductive post is at least partially encapsulated by a first mold compound, and the second thermally conductive post is at least partially encapsulated by a second mold compound.

In one example of an electronic device package, the thermally conductive post is electrically conductive and electrically coupled to the substrate and the electronic component.

In one example of an electronic device package, an electrical interconnect interface of the electronic component is oriented toward the substrate.

In one example of an electronic device package, the thermally conductive post is electrically coupled to the electronic component via a solder ball coupled to the electrical interconnect interface and the thermally conductive post.

In one example of an electronic device package, the thermally conductive post has an electrical resistance less than about 0.02 ohms.

In one example, an electronic device package precursor comprises a mold compound at least partially encapsulating the thermally conductive post.

In one example of an electronic device package, the thermally conductive post comprises a plurality of thermally conductive posts and a laterally oriented bridge extending between two of the thermally conductive posts in communication with the electronic component to provide electrical routing.

In one example, an electronic device package precursor comprises a spacer disposed on the substrate and a second electronic component supported by the spacer.

In one example of an electronic device package, the thermally conductive post has a thickness of at least about 100 μm.

In one example of an electronic device package, the thermally conductive post has a height of at least about 120 μm.

In one example of an electronic device package, the thermally conductive post comprises a metal material.

In one example of an electronic device package, the metal material comprises copper.

In one example of an electronic device package, the thermally conductive post comprises a plurality of thermally conductive posts.

In one example, there is provided an electronic device package precursor comprising a substrate, and a thermally conductive post extending from the substrate.

In one example, an electronic device package precursor comprises a mold compound at least partially encapsulating the thermally conductive post.

In one example of an electronic device package precursor, a top portion of the thermally conductive post is covered by the mold compound.

In one example of an electronic device package precursor, a top portion of the mold compound and a top portion of the thermally conductive post form a planar surface.

In one example of an electronic device package precursor, the mold compound comprises an epoxy.

In one example of an electronic device package precursor, a side portion of the thermally conductive post is exposed to atmosphere.

In one example, an electronic device package precursor comprises a second thermally conductive post extending from the substrate.

In one example of an electronic device package precursor, the first thermally conductive post is at least partially encapsulated by a first mold compound, and the second thermally conductive post is at least partially encapsulated by a second mold compound.

In one example of an electronic device package precursor, the thermally conductive post is electrically conductive and electrically coupled to the substrate.

In one example of an electronic device package precursor, the thermally conductive post has an electrical resistance less than about 0.02 ohms.

In one example, an electronic device package precursor comprises a mold compound at least partially encapsulating the thermally conductive post.

In one example of an electronic device package precursor, the thermally conductive post comprises a plurality of thermally conductive posts and a laterally oriented bridge extending between two of the thermally conductive posts for communication with an electronic component to provide electrical routing.

In one example, an electronic device package precursor comprises a spacer disposed on the substrate and an electronic component supported by the spacer.

In one example of an electronic device package precursor, the thermally conductive post has a thickness of at least about 100 μm.

In one example of an electronic device package precursor, the thermally conductive post has a height of at least about 120 μm.

In one example of an electronic device package precursor, the thermally conductive post comprises a metal material.

In one example of an electronic device package precursor, the metal material comprises copper.

In one example of an electronic device package precursor, the thermally conductive post comprises a plurality of thermally conductive posts.

In one example, there is provided a computing system comprising a motherboard, and an electronic device package operably coupled to the motherboard. The electronic device package comprises a substrate, a thermally conductive post extending from the substrate, and an electronic component supported by the thermally conductive post, wherein the thermally conductive post facilitates heat transfer between the electronic component and the substrate.

In one example of a computing system, the computing system comprises a desktop computer, a laptop, a tablet, a smartphone, a server, a wearable electronic device, or a combination thereof.

In one example of a computing system, the computing system further comprises a processor, a memory device, a cooling system, a radio, a slot, a port, or a combination thereof operably coupled to the motherboard.

In one example there is provided a method for making an electronic device package comprising obtaining a substrate, and disposing a thermally conductive post on the substrate.

In one example, a method for making an electronic device package comprises disposing an electronic component on the thermally conductive post such that the electronic component is supported by the thermally conductive post, wherein the thermally conductive post facilitates heat transfer between the electronic component and the substrate.

In one example, a method for making an electronic device package comprises orienting an electrical interconnect interface of the electronic component away from the substrate.

In one example, a method for making an electronic device package comprises electrically coupling the electronic component to the substrate via a wirebond extending between the electrical interconnect interface and the substrate.

In one example, a method for making an electronic device package comprises at least partially encapsulating the thermally conductive post in a mold compound.

In one example of a method for making an electronic device package, a top portion of the thermally conductive post is covered by the mold compound.

In one example, a method for making an electronic device package comprises removing mold compound covering the top portion of the thermally conductive post.

In one example of a method for making an electronic device package, removing mold compound comprises polishing.

In one example of a method for making an electronic device package, mold compound is removed such that a top portion of the mold compound and the top portion of the thermally conductive post form a planar surface.

In one example of a method for making an electronic device package, the mold compound comprises an epoxy.

In one example of a method for making an electronic device package, a side portion of the thermally conductive post is exposed to atmosphere.

In one example of a method for making an electronic device package, disposing an electronic component on the thermally conductive post comprises disposing a plurality of electronic components in a stacked arrangement on the thermally conductive post.

In one example, a method for making an electronic device package comprises disposing a second thermally conductive post on the substrate, wherein the first thermally conductive post supports all of the plurality of electronic components and the second thermally conductive posts supports fewer than all of the plurality of electronic components.

In one example, a method for making an electronic device package comprises at least partially encapsulating the first thermally conductive post in a first mold compound, and the second thermally conductive post in a second mold compound.

In one example of a method for making an electronic device package, the thermally conductive post is electrically conductive, and further comprising electrically coupling the thermally conductive post to the substrate and the electronic component.

In one example, a method for making an electronic device package comprises orienting an electrical interconnect interface of the electronic component toward the substrate.

In one example of a method for making an electronic device package, the thermally conductive post is electrically coupled to the electronic component via a solder ball coupled to the electrical interconnect interface and the thermally conductive post.

In one example of a method for making an electronic device package, the thermally conductive post has an electrical resistance less than about 0.02 ohms.

In one example, a method for making an electronic device package comprises at least partially encapsulating the thermally conductive post in a mold compound.

In one example of a method for making an electronic device package, the thermally conductive post comprises a plurality of thermally conductive posts, and further comprising forming a laterally oriented bridge extending between two of the thermally conductive posts for communication with the electronic component to provide electrical routing.

In one example, a method for making an electronic device package comprises disposing a spacer on the substrate and disposing a second electronic component on the spacer such that the second electronic component is supported by the spacer.

In one example of a method for making an electronic device package, disposing a thermally conductive post on the substrate comprises a depositing thermally conductive material on the substrate.

In one example of a method for making an electronic device package, depositing thermally conductive material comprises plating, printing, sputtering, or a combination thereof.

In one example of a method for making an electronic device package, the thermally conductive post has a thickness of at least about 100 μm.

In one example of a method for making an electronic device package, the thermally conductive post has a height of at least about 120 μm.

In one example of a method for making an electronic device package, the thermally conductive post comprises a metal material.

In one example of a method for making an electronic device package, the metal material comprises copper.

In one example of a method for making an electronic device package, the thermally conductive post comprises a plurality of thermally conductive posts.

Circuitry used in electronic components or devices (e.g. a die) of an electronic device package can include hardware, firmware, program code, executable code, computer instructions, and/or software. Electronic components and devices can include a non-transitory computer readable storage medium which can be a computer readable storage medium that does not include signal. In the case of program code execution on programmable computers, the computing devices recited herein may include a processor, a storage medium readable by the processor (including volatile and non-volatile memory and/or storage elements), at least one input device, and at least one output device. Volatile and non-volatile memory and/or storage elements may be a RAM, EPROM, flash drive, optical drive, magnetic hard drive, solid state drive, or other medium for storing electronic data. Node and wireless devices may also include a transceiver module, a counter module, a processing module, and/or a clock module or timer module. One or more programs that may implement or utilize any techniques described herein may use an application programming interface (API), reusable controls, and the like. Such programs may be implemented in a high level procedural or object oriented programming language to communicate with a computer system. However, the program(s) may be implemented in assembly or machine language, if desired. In any case, the language may be a compiled or interpreted language, and combined with hardware implementations.

While the forgoing examples are illustrative of the specific embodiments in one or more particular applications, it will be apparent to those of ordinary skill in the art that numerous modifications in form, usage and details of implementation can be made without departing from the principles and concepts articulated herein.

1. An electronic device package, comprising:
a substrate;
a thermally conductive post extending from the substrate; and
an electronic component supported by the thermally conductive post, wherein the thermally conductive post facilitates heat transfer between the electronic component and the substrate.

2. The electronic device package of claim 1, wherein an electrical interconnect interface of the electronic component is oriented away from the substrate.

3. The electronic device package of claim 2, wherein the electronic component is electrically coupled to the substrate via a wirebond extending between the electrical interconnect interface and the substrate.

4. The electronic device package of claim 1, further comprising a mold compound at least partially encapsulating the thermally conductive post.

5. The electronic device package of claim 0, wherein a top portion of the mold compound and a top portion of the thermally conductive post form a planar surface, and the electronic component is disposed on at least a portion of the planar surface.

6. The electronic device package of claim 0, wherein the mold compound comprises an epoxy.

7. The electronic device package of claim 1, wherein a side portion of the thermally conductive post is exposed to atmosphere.

8. The electronic device package of claim 1, wherein the electronic component comprises a plurality of electronic components in a stacked arrangement.

9. The electronic device package of claim 0, further comprising a second thermally conductive post extending from the substrate, wherein the first thermally conductive post supports all of the plurality of electronic components and the second thermally conductive posts supports fewer than all of the plurality of electronic components.

10. The electronic device package of claim 0, wherein the first thermally conductive post is at least partially encapsulated by a first mold compound, and the second thermally conductive post is at least partially encapsulated by a second mold compound.

11. The electronic device package of claim 1, wherein the thermally conductive post is electrically conductive and electrically coupled to the substrate and the electronic component.

12. The electronic device package of claim 0, wherein an electrical interconnect interface of the electronic component is oriented toward the substrate.

13. The electronic device package of claim 0, wherein the thermally conductive post is electrically coupled to the electronic component via a solder ball coupled to the electrical interconnect interface and the thermally conductive post.

14. The electronic device package of claim 0, wherein the thermally conductive post has an electrical resistance less than about 0.02 ohms.

15. The electronic device package of claim 0, further comprising a mold compound at least partially encapsulating the thermally conductive post.

16. The electronic device package of claim 0, wherein the thermally conductive post comprises a plurality of thermally conductive posts and a laterally oriented bridge extending between two of the thermally conductive posts in communication with the electronic component to provide electrical routing.

17. The electronic device package of claim 1, further comprising a spacer disposed on the substrate and a second electronic component supported by the spacer.

18. The electronic device package of claim 1, wherein the thermally conductive post has a thickness of at least about 100 μm.

19. The electronic device package of claim 1, wherein the thermally conductive post has a height of at least about 120 μm.

20. The electronic device package of claim 1, wherein the thermally conductive post comprises a metal material.

21. The electronic device package of claim 0, wherein the metal material comprises copper.

22. The electronic device package of claim 1, wherein the thermally conductive post comprises a plurality of thermally conductive posts.

23-43. (canceled)

44. A method for making an electronic device package, comprising:
obtaining a substrate; and
disposing a thermally conductive post on the substrate.

45. The method of claim 0, further comprising disposing an electronic component on the thermally conductive post such that the electronic component is supported by the thermally conductive post, wherein the thermally conductive post facilitates heat transfer between the electronic component and the substrate.

46. The method of claim 0, further comprising orienting an electrical interconnect interface of the electronic component away from the substrate.

47. The method of claim 0, further comprising electrically coupling the electronic component to the substrate via a wirebond extending between the electrical interconnect interface and the substrate.

48. The method of claim 0, further comprising at least partially encapsulating the thermally conductive post in a mold compound.

49-71. (canceled)
